(19) United States
(12) Patent Application Publication
(10) Pub. No.: US 2015/0040977 A1
(43) Pub. Date: Feb. 12, 2015

(54) BACKSHEET FILM WITH IMPROVED HYDROLYTIC STABILITY

(71) Applicant: 3M INNOVATIVE PROPERTIES COMPANY, Saint Paul, MN (US)

(72) Inventors: Karnav D. Kanuga, Woodbury, MN (US); Kevin M. Hamer, Saint Paul, MN (US); Thomas J. Blong, Woodbury, MN (US)

(21) Appl. No.: 14/388,038

(22) PCT Filed: Feb. 8, 2013
(86) PCT No.: PCT/US13/25303

§ 371 Date: Sep. 25, 2014

Related U.S. Application Data
(60) Provisional application No. 61/618,193, filed on Mar. 30, 2012.

(51) Int. Cl. H01L 31/048; B32B 37/18

(52) U.S. Cl. CPC H01L 31/0487; H01L 31/0481; B32B 37/182
USPC 136/256; 136/252; 156/60

(57) ABSTRACT

This disclosure generally relates to films capable of use in photovoltaic modules, to films, to methods of use and manufacture of these films, and to photovoltaic cells and/or modules including these films. One exemplary embodiment of such a film is a barrier layer having a moisture vapor transmission rate of less than 3.0 g/m2-day, wherein the barrier layer includes a polyethylene terephthalate having an apparent crystal size of less than 65 angstroms. Another exemplary embodiment of such a film is a multilayer film for use as a backsheet in a photovoltaic module including: a first layer including a fluoropolymer; a second layer including a polyethylene terephthalate having an apparent crystal size of less than 65 angstroms; and a third layer including an olefinic polymer. The first layer and the third layer are bonded to opposing major surfaces of the second layer.

### TECHNICAL FIELD

This disclosure generally relates to films capable of use in photovoltaic modules, to multilayer films, to methods of use and manufacture of these films, and to photovoltaic cells and/or modules including these films.

### BACKGROUND

Renewable energy is energy derived from natural resources that can be replenished, such as sunlight, wind, rain, tides, and geothermal heat. The demand for renewable energy has grown substantially with advances in technology and increases in global population. Although fossil fuels provide for the vast majority of energy consumption today, these fuels are non-renewable. The global dependence on these fossil fuels has not only raised concerns about their depletion but also environmental concerns associated with emissions that result from burning these fuels. As a result of these concerns, countries worldwide have been establishing initiatives to develop both large-scale and small-scale renewable energy resources. One of the promising energy resources today is sunlight. Globally, millions of households currently obtain power from solar photovoltaic systems. The rising demand for solar power has been accompanied by a rising demand for devices and materials capable of fulfilling the requirements for these applications.

Photovoltaic modules used outdoors and are thus subject to continuous exposure to the elements. Consequently, a technical challenge in designing and manufacturing photovoltaic modules and their components is achieving long-term (e.g., 25 years) durability when subjected to harsh environmental conditions, including, for example, water vapor, wind, and sunlight.

Photovoltaic modules include a back-side material that electrically insulates the solar module and protects the solar module from the environment (e.g., moisture and dirt). Typical back-side materials include, for example, a polymeric or glass sheet. Polymeric back-side materials (often referred to as “backsheets”) typically include at least one layer including a fluoropolymer and multiple other layers including polymers (e.g., polyethene terephthalate (PET) polymers, polyethene naphthalate (PEN) polymers, polyesters, and polyamides). For example, U.S. Publication No. 2008/0216889 and U.S. Pat. No. 7,638,186 describe a backsheet including a PET.

Attempts to improve durability or performance have involved the use of metal foils, inorganic coatings, and/or multiple layers of fluoropolymers. These endeavors can result in constructions that are quite expensive. Additionally, some of the multilayer films are stiffer (i.e. have a higher modulus) and are thus more difficult to apply to a solar module. Additionally, the conventional constructions typically require that the completed, typically multilayer, construction be subjected to a heating cycle prior to lamination so that the entire construction can be successfully laminated.

### SUMMARY

The inventors of the present disclosure recognized the need for a more durable polymeric backsheet. The inventors of the present disclosure recognized the need for a polymeric backsheet with improved performance. The inventors of the present disclosure found various embodiments of polymeric films that exhibit enhanced durability and performance.

One embodiment of a multilayer film for use as a backsheet in a photovoltaic module comprises a first layer including a fluoropolymer; a second layer including a polyethylene terephthalate having an apparent crystal size of less than 65 angstroms; and a third layer including a polymer. The first layer and the third layer are bonded to opposing major surfaces of the second layer.

Another embodiment of a multilayer film for use as a backsheet in a photovoltaic module comprises: a first layer including a fluoropolymer; a second layer including a polyethylene terephthalate having an apparent crystal size of less than 65 angstroms, an intrinsic viscosity of at least 0.65, and less than 20 milliequivalents per kilogram of acid end groups; and a third layer including an olefinic polymer. The first layer and the third layer are bonded to opposing major surfaces of the second layer and the multilayer film exhibits no visual cracks after 96 hours of Pressure Cooker Testing.

Another embodiment of a multilayer film for use as a backsheet in a photovoltaic module comprises: a barrier layer having a moisture vapor transmission rate of less than 3.0 g/m²-day; and a polyethylene terephthalate layer having an apparent crystal size of less than 65 angstroms.

One exemplary method of making a multilayer film, comprises: providing a layer including a polyethylene terephthalate having an apparent crystal size of less than about 65 angstroms; and positioning a barrier layer adjacent to the layer including polyethylene terephthalate. In some embodiments, the method further comprises attaching the multilayer film to glass. The multilayer film on the glass exhibits no visual cracks after 96 hours in a 121° C. and 100% relative humidity environment. In some embodiments, the method further comprises adding an olefin layer.

In all of these embodiments, one or more of the following may also be present. In some embodiment, the polyethylene terephthalate has an intrinsic viscosity of at least 0.63. In some embodiment, the polyethylene terephthalate has an intrinsic viscosity of at least 0.64. In some embodiment, the polyethylene terephthalate has an intrinsic viscosity of at least 0.65. In some embodiment, the polyethylene terephthalate has an intrinsic viscosity of at least 0.66. In some embodiment, the polyethylene terephthalate has an intrinsic viscosity of at least 0.67. In some embodiment, the polyethylene terephthalate has an intrinsic viscosity of at least 0.68. In some embodiment, the polyethylene terephthalate has an intrinsic viscosity of at least 0.69. In some embodiment, the polyethylene terephthalate has an intrinsic viscosity of at least 0.70.

In some embodiment, the polyethylene terephthalate has less than about 23 milliequivalents per kilogram of acid end groups. In some embodiment, the polyethylene terephthalate has less than about 20 milliequivalents per kilogram of acid end groups. In some embodiments, the multilayer film when laminated to glass exhibits no visual cracks after 3000 hours in an 85° C. and 85% relative humidity environment. In some embodiments, the multilayer film exhibits no visual cracks after 96 hours of Pressure Cooker Testing. In some embodiments, the multilayer film exhibits no visual cracks after 100 hours of Pressure Cooker Testing. In some embodiments, the multilayer film exhibits no visual cracks after 110 hours of Pressure Cooker Testing. In some embodiments, the multilayer film exhibits no visual cracks after 120 hours of Pressure Cooker Testing.

In some embodiments the PET has an apparent crystal size of 65 angstroms or less. In some embodiments, the PET has an apparent crystal size of 63 angstroms or less. In some embodiments, the PET has an apparent crystal size of 62 angstroms or less. In some embodiments, the PET has an apparent crystal size of 61 angstroms or less. In some embodiments, the PET has an apparent crystal size of 60 angstroms or less.

In some embodiments, the first layer includes at least one of interpolymerized units of fluorinated monomers and non-fluorinated monomers. In some embodiments, the fluoropolymer is semi-crystalline. In some embodiments, the third layer comprises interpolymerized units of ethylene vinyl acetate. In some embodiments, the multilayer film further includes a tie layer between at least one of (a) the first layer and the second layer and (b) the second layer and the third layer. In some embodiments, the multilayer film further includes an adhesive layer between at least one of (a) the first layer and the second layer and (b) the second layer and the third layer. In some embodiments, the multilayer film includes a silane and the silane is in at least one of the following layers: the first layer, the second layer, the third layer, a layer between the first layer and the second layer, and a layer between the second layer and the third layer. In some embodiments, any of the multilayer films described herein are applied to a substrate. In some embodiments, the substrate is a solar cell. In some embodiments, the solar cell is placed in a solar module.

Another embodiment of the present disclosure is a solar cell including a film as described above.

Another embodiment of the present disclosure is a solar module including a film as described above.

### BRIEF DESCRIPTION OF THE DRAWINGS

The present disclosure may be more completely understood in consideration of the following detailed description of various embodiments of the disclosure in connection with the accompanying drawings, in which:

FIG. 1 is a schematic cross-sectional view of one exemplary film capable of use as a backsheet.

FIG. 2 is a schematic cross-sectional view of one exemplary film capable of use as a backsheet.

The figures are not necessarily to scale. It will be understood that the use of a number to refer to a component in a given figure is not intended to limit the component in another figure labeled with the same number.

### DETAILED DESCRIPTION

In the following detailed description, reference may be made to the accompanying set of drawings that form a part hereof and in which are shown by way of illustration several specific embodiments. It is to be understood that other embodiments are contemplated and may be made without departing from the scope or spirit of the present disclosure. The following detailed description, therefore, is not to be taken in a limiting sense.

The present disclosure generally relates to multilayer films capable of use in solar modules as backsheets. The films of the present disclosure can be used in any type of photovoltaic solar module.

In one exemplary embodiment, the film is capable of use as a backsheet in a photovoltaic module and includes a barrier layer having a moisture vapor transmission rate of less than 3 g/m²-day and a polyethylene terephthalate layer having an apparent crystal size of less than 65 angstroms. In some embodiments, the barrier layer has a moisture vapor transmission rate of less than 2.5 g/m²-day. In some embodiments, the barrier layer has a moisture vapor transmission rate of less than 2.0 g/m²-day. As used herein, the term “barrier layer” is meant to refer to any inorganic or organic layer having a moisture vapor transmission rate of less than 3 g/m²-day when measured as described herein. Films of this type can optionally include additional layers, as will be discussed in greater detail below.

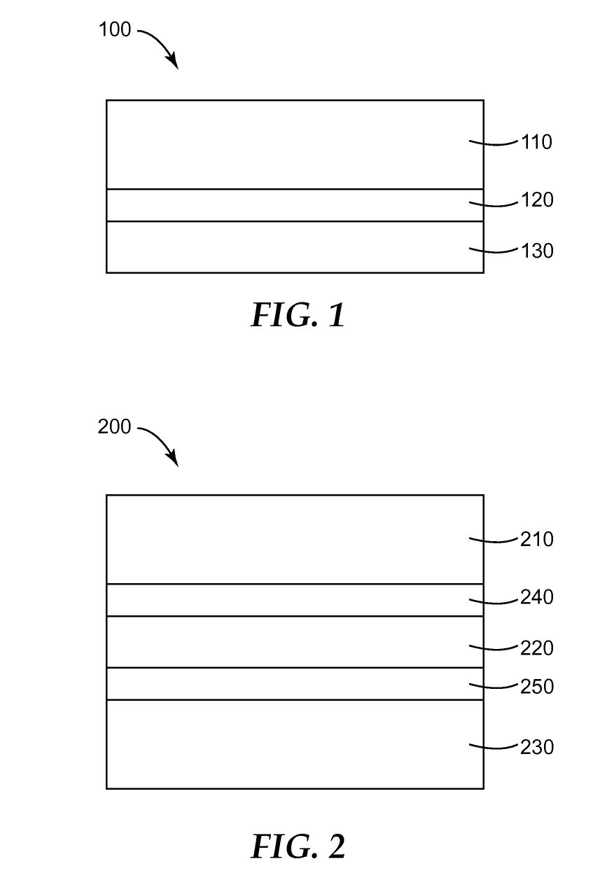

In another exemplary embodiment, a film capable of use as a backsheet in a photovoltaic module is a multilayered film. One specific implementation of a multilayer film is shown schematically in FIG. 1. FIG. 1 shows a multilayer film 100 capable of use as a backsheet in a photovoltaic module. Film 100 includes: (1) a first layer 110 (in some embodiments, this layer includes a fluoropolymer); (2) a second layer 120 including a polyethylene terephthalate having an apparent crystal size of less than 65 angstroms; and (3) a polymeric third layer 130. As shown in FIG. 1, first layer 110 and third layer 130 are bonded to opposing major surfaces of the second layer 120.

Another specific implementation of a multilayer film is shown schematically in FIG. 2. FIG. 2 shows a multilayer film 200 capable of use as a backsheet in a photovoltaic module. Film 200 includes: (1) a first layer 210 (in some embodiment, this layer includes a fluoropolymer); (2) a second layer 220 including a polyethylene terephthalate having an apparent crystal size of less than 65 angstroms; (3) a third layer 230 including a polymer; (4) an adhesive layer 240 between first layer 210 and second layer 220; and (5) an adhesive layer 250 between second layer 220 and third layer 230. In some embodiments, only one of the adhesive layers 240 and 250 are present. In some embodiments, at least one of adhesive layers 240 and 250 is a tie layer.

In some embodiments, the backsheet has a thickness effective to provide the electrical breakdown voltage of at least 10 kV or at least 20 kV and or some or all of the mechanical properties as described herein. In some embodiments, the backsheet has a thickness between about 200 μm and about 400 μm. In some embodiments, the backsheet has a thickness of between about 250 μm and about 350 μm.

In some embodiments, the backsheet includes one or more of carbon particles and/or pigments (e.g., white pigments). In some embodiments, the backsheet is black in colour due the presence of substantial amounts of carbon particles. The carbon particles may be modified, for example surface treated, coated or may contain functionalised groups (e.g., by chemical reaction with chemical modifiers or by adsorption of chemicals). Carbon particles include graphite, fullerenes, nanotubes, soot, carbon blacks (e.g., carbon black, acetylene black, ketjen black). Typically, the backsheet portion/layer may contain from about 1% to about 6% or up to about 10% weight based on the weight of the layer of carbon particles. The loading with carbon particles may be increased but in that case the layer may become electron conductive. In this case the layer can be earthed when it is incorporated into a solar module. However, the backsheet can be of a different colour if pigments or paints are used.

In some embodiments, the backsheet includes one or more of antioxidants, UV-absorbers, cross-linkers, flame retardants, photoluminescent additives, and/or anti dripping agents. The amount of these ingredients may be individually or combined be from about 0.01%-wt to about 40%-wt. It has been found that the film is resistant enough to only show little yellowing upon extensive heat, dampness, or UV treatment. In some embodiments, the backsheet includes up to 35% or up to 30% or up to 20% or up to 10% by weight of flame retardant based on the weight of the layer and has a dielectric break down voltage of at least 20 kV. The inclusion of flame retardants or anti-dripping agents may results in a film having good anti-burning behaviour while maintaining the desired mechanical, electrical, heat, and moisture properties described herein.

In some embodiments, the film exhibits no visual cracks after 3000 hours in an 85° C. and 85% relative humidity environment. In some embodiments, the film exhibits no visual cracks after 96 hours in a 121° C. and 100% relative humidity environment. In some embodiments, the film exhibits no visual cracks after 100 hours in a 121° C. and 100% relative humidity environment. In some embodiments, the film exhibits no visual cracks after 110 hours in a 121° C. and 100% relative humidity environment. In some embodiments, the film exhibits no visual cracks after 120 hours in a 121° C. and 100% relative humidity environment.

Optionally, one or more layers in the backsheet may include known adjuvants such as antioxidants, light stabilizers, conductive materials, carbon black, titanium dioxide, graphite, fillers, lubricants, pigments, plasticizers, processing aids, stabilizers, and the like including combinations of such materials. In addition, metallized coatings and reinforcing materials also may be used in the backsheet. These include, e.g., polymeric or fiberglass scrim that can be bonded, woven or non-woven. Such a material optionally may be used as a separate layer or included within a layer in a multi-layer embodiment.

The layer(s) of the backsheet are described in greater detail below.

### PET Layer

Apparent crystal size can vary depending on various factors, including, for example, crystal shape, crystallization time, crystallization temperature, and manufacturing process. In some implementations, the temperature during tentering can be varied to affect the apparent crystal size. In some embodiments, the tentering temperature is less than 230° C. In some embodiments, the tentering temperature is less than 225° C. The PET layer including PET having an apparent crystal size of less than 65 angstroms. In some embodiments, the crystal size is less than 64 angstroms. In some embodiments, the crystal size is less than 63 angstroms. In some embodiments, the crystal size is less than 62 angstroms. In some embodiments, the crystal size is less than 61 angstroms. In some embodiments, the crystal size is less than 60 angstroms.

In some embodiments, the polyethylene terephthalate has an intrinsic viscosity of at least 0.70. In some embodiments, the polyethylene terephthalate has less than 23 milliequivalents per kilogram of acid end groups. In some embodiments, the polyethylene terephthalate has less than 20 milliequivalents per kilogram of acid end groups.

In some embodiments, the PET layer may include additional polymers. Some exemplary additional polymers include: polyethylenepthalate (PEN), polyarylates; polyamides, such as polyamide 6, polyamide 11, polyamide 12, polyamide 46, polyamide 66, polyamide 69, polyamide 610, and polyamide 612; aromatic polyamides and polyphthalamides; thermoplastic polyimides; polyetherimides; polycarbonates, such as the polycarbonate of bisphenol A; acrylic and methacrylic polymers such as polymethyl methacrylate; polyketones, such as poly(aryl ether ether ketone) (PEEK) and the alternating copolymers of ethylene or propylene with carbon monoxide; polyethers, such as polyphenylene oxide, poly(dimethylphenylene oxide), polyethylene oxide and polyoxymethylene; and sulfur-containing polymers such as polyphenylene sulfide, polysulfones, and polyethersulfones.

In some embodiments, the PET layer is pre-shrunk. The shrinking of the PET layer results in a layer that will shrink less than 1.5% of its total length in either planer direction when exposed to a temperature of 150° C. during a period of 15 minutes, in accordance with ASTM D 2305-02. Such films are commercially available or can be prepared by exposing the film, under minimal tension, to a temperature above its glass transition temperature, preferable above 150° C. for a period of time sufficient to pre-shrink the film. Such thermal treatment can occur either as a post treatment or during the initial manufacturing process used to produce the film.

In some embodiments, the PET layer has a thickness between about 4 mils to about 10 mils microns. In some embodiments, the PET layer has a thickness between about 4.5 mils to about 7 mils microns.

### Fluoropolymer Layer

Not all embodiments include a fluoropolymer layer; this layer is optional. A fluoropolymer layer is not required, but may be included in some embodiments. Where a fluoropolymer layer is included, the fluoropolymer can be selected from a variety of fluoropolymers. Such fluoropolymers are typically homopolymers or copolymers of TFE (tetrafluoro ethylene), VDF (vinylidene fluoride), VF (vinylfluoride), (chlorotrifluoroethylene), or CTFE with other fluorinated or non-fluorinated monomers. Representative materials include copolymers of tetrafluoroethylene-ethylene (ETFE), tetrafluoroethylene-hexafluoropropylene (FEP), tetrafluoroethylene-perfluoroalkoxyvinlyether (PFA), copolymers of vinylidene fluoride and chlorotrifluoroethylene, tetrafluoroethylene-hexafluoropropylene-ethylene (HTE), polyvinyl fluoride (PVF), copolymers of vinylidene fluoride and chlorotrifluoroethylene, or a copolymer derived from tetrafluoroethylene (TFE), hexafluoropropylene (HFP), and vinylidene fluoride (VDF), such as the THV series available from 3M Company, Saint Paul, Minn.

The fluoropolymer layer may be capable of providing low moisture permeability characteristics (“barrier” properties) to the construction in order to protect internal components of the film or of the preferred solar cell application.

A preferred class of fluorinated copolymers suitable as the fluoropolymer layer are those having interpolymerized units derived from tetrafluoroethylene, hexafluoropropylene, and vinylidene fluoride, and optionally a perfluoro alkyl or alkoxy vinyl ether. Preferably these polymers have less than about 30 weight percent (wt %) VDF, more preferably between about 10 and about 25 wt %, of its interpolymerized units derived from VDF. A non-limiting example includes THV 500 available from Dyneon LLC, Oakdale, Minn.

Another preferred class of materials suitable for use as the fluoropolymer layer include various combinations of interpolymerized units of TFE and ethylene along with other additional monomers such as HFP, perfluoro alkyl or alkoxy vinyl ethers (PAVE or PAOVE). An example is HTE 1510, available from Dyneon LLC, Oakdale, Minn.

### Polymeric Layer

Not all embodiments include a polymeric layer; this layer is optional. A polymeric layer is not required, but may be included in some embodiments. Where a polymeric layer is included, any polymer may be used, and the layer can be single or multilayered. In some embodiments, olefinic polymers are used. Some exemplary olefinic polymers include, for example, polymers and copolymers derived from one or more olefinic monomers of the general formula CH₂═CHR″, wherein R″ is hydrogen or C₁₋₁₈ alkyl. Examples of such olefinic monomers include propylene, ethylene, and 1-butene, with ethylene being generally preferred. Representative examples of polyolefins derived from such olefinic monomers include polyethylene, polypropylene, polybutene-1, poly(3-methylbutene), poly(4-methylpentene) and copolymers of ethylene with propylene, 1-butene, 1-hexene, 1-octene, 1-decene, 4-methyl-1-pentene, and 1-octadecene.

The olefinic polymers may optionally comprise a copolymer derived from an olefinic monomer and one or more further comonomers that are copolymerizable with the olefinic monomer. These comonomers can be present in the polyolefin in an amount in the range from about 1 wt-% to about 15 wt-% based on the total weight of the polyolefin. In some embodiments, the range is between about 2 wt-% and 13 wt-%. Useful such comonomers include, for example, vinyl ester monomers such as vinyl acetate, vinyl propionate, vinyl butyrate, vinyl chloroacetate, vinyl chloropropionate; acrylic and alpha-alkyl acrylic acid monomers, and their alkyl esters, amides, and nitriles such as acrylic acid, methacrylic acid, ethacrylic acid, methyl acrylate, ethyl acrylate, N,N-dimethyl acrylamide, methacrylamide, acrylonitrile; vinyl aryl monomers such as styrene, o-methoxystyrene, p-methoxystyrene, and vinyl naphthalene; vinyl and vinylidene halide monomers such as vinyl chloride, vinylidene chloride, and vinylidene bromide; alkyl ester monomers of maleic and fumaric acid such as dimethyl maleate, and diethyl maleate; vinyl alkyl ether monomers such as vinyl methyl ether, vinyl ethyl ether, vinyl isobutyl ether, and 2-chloroethyl vinyl ether; vinyl pyridine monomers; N-vinyl carbazole monomers, and N-vinyl pyrrolidine monomers.

Optionally, the polymeric layer may be cross-linked. Any cross-linking method can be used, including, for example, chemical or e-beam cross-linking.

The olefinic polymers may also contain a metallic salt form of a polyolefin, or a blend thereof, which contains free carboxylic acid groups. Illustrative of the metals which can be used to provide the salts of said carboxylic acid polymers are the one, two and three valence metals such as sodium, lithium, potassium, calcium, magnesium, aluminum, barium, zinc, zirconium, beryllium, iron, nickel and cobalt.

The olefinic polymers may also include blends of these polyolefins with other polyolefins, or multi-layered structures of two or more of the same or different polyolefins. In addition, they may contain conventional adjuvants such as antioxidants, light stabilizers, acid neutralizers, fillers, antiblocking agents, pigments, primers and other adhesion promoting agents.

Preferred olefinic polymers include homopolymers and copolymers of ethylene with alpha-olefins as well as copolymers of ethylene and vinyl acetate. Representative materials of the latter include Elvax 150, 3170, 650 and 750 available from E.I. du Pont de Nemours and Company.

In some embodiments, it is preferred that the backsheet does not significantly delaminate during use. That is, the adhesive bond strength between the different layers of the multi-layer article should be sufficiently strong and stable so as to prevent the different layers from separating on exposure to, for example, moisture, heat, cold, wind, chemicals and or other environmental exposure. The adhesion may be required between non-fluoropolymer layers or adjacent the fluoropolymer layer. Various methods of increasing interlayer adhesion in all cases are generally known by those of skill in the art. The backsheet portion may also include a bonding interface or agent between said outer and intermediate layers.

### Adhesives, Tie Layers, and Primers

Not all embodiments include an adhesive layer, tie layer, or primer; this layer (or these layers) is/are optional. An adhesive or tie layer is not required, but may be included in some embodiments. The adhesive, tie, or primer material may be present as a separate layer or may be included within another layer.

Where an adhesive layer is included, any known adhesive may be used to adhere adjacent layers together. Some exemplary adhesives include those described in, for example, U.S. Published Application No. 2005/0080210 (issued as U.S. Pat. No. 6,911,512), U.S. Pat. No. 6,767,948, and U.S. Pat. No. 6,753,087, all of which are incorporated herein by reference. Those of ordinary skill in the art are capable of matching the appropriate the conventional bonding techniques to the selected multilayer materials to achieve the desired level of interlayer adhesion.

In some embodiments, one or more tie layers isare included. In some embodiments, the tie layer(s) improve interlayer adhesion with the fluoropolymer. In some embodiments, the tie layer achieves this improvement by blending a base and an aromatic material such as a catechol novolak resin, a catechol cresol novolak resin, a polyhydroxy aromatic resin (optionally with a phase transfer catalyst) with the fluoropolymer and then applying to either layer prior to bonding. Alternatively, this composition may be used as the fluoropolymer layer without separate tie layer as disclosed, for example, in U.S. Published Application No. 2005/0080210 (issued as U.S. Pat. No. 6,911,512), incorporated herein in its entirety. Another exemplary tie layer includes a combination of a base, a crown ether, and a non-fluoropolymer, as generally described in U.S. Pat. No. 6,767,948, incorporated herein in its entirety. Another exemplary tie layer includes an amino substituted organosilane, as described in, for example, U.S. Pat. No. 6,753,087, incorporated herein in its entirety. The organosilane may optionally be blended with a functionalized polymer.

Adhesion between non-fluoropolymer layers may also be accomplished in a variety of ways including the application of anhydride or acid modified polyolefins, the application of silane primers, utilization of electron beam radiation, utilization of ultraviolet light and heat, or combinations thereof.

Other additives may be included, and variations to the above components may be included, as is described in U.S. Publication No. 2008/0216889 and U.S. Pat. No. 7,638,186, both of which are incorporated herein by reference.

### EXAMPLES

### Pressure Cooker Test Method

This test provides a means to accelerate the aging of PET and/or photovoltaic backsheets in an environment of high temperature, pressure, and relative humidity. All samples were laminated to glass using an EVA encapsulant, as specified below. The resulting glass-film construction was tested under the conditions described below.

A 1.62 cu.ft. HAST (highly accelerated stress test) pressure cooker commercially available from Espec, Hudsonville, Mich. under the trade designation “EHS-221M” was programmed for a temperature of 121° C., pressure of 2.0 atmospheres and 100% relative humidity. Samples were placed in the vessel and removed after 48, 60, 72, 96, 100, 106, 116, and 126 hour intervals and checked for evidence of cracking.

Using a light table, the films were inspected for cracks in the layers. If a crack was not visible at a given interval, it was considered to pass the test. If a crack was visible at a given interval, it was considered to fail the test.

### Elongation at Break

Elongation at break was determined as follows: a 7.6 cm×15.2 cm (3 inches×6 inches) sample of the polymer film to be tested was taped with 2.5 cm (1 inch) masking tape along the top edge. A 5-pronged cutter was used on a clean cutting board to cut five replicate 1.3 cm (½ in) strips in the sample from the taped edge to the free edge. These samples were placed in the “EHS-221M” pressure cooker and were removed at 24, 48, 72, and 96 hrs as shown in Table 1. Elongation at break was measured on each of the 5 replicate strips and an average was taken according to ASTM D882-10 using a 2 inches/min crosshead speed and a 5.1 cm (2 inches) grip separation gauge length using a “MTS Insight” tensile testing instrument (commercially available from MTS, Eden Prairie, Minn.).

### Damp Heat Test Method

This test provides a means to accelerate the aging of PET and/or photovoltaic backsheets in an 85° C. and 85% relative humidity (RH) environment. A 15 cm×30 cm (6 inches×12 inches) sample was laminated to glass using an encapsulant (commercially available from Saint Gobain under the trade name “LightSwitch”). The laminated structure was placed in a damp heat chamber at 85° C. and 85% RH and was removed at 1000 hrs, 2000 hrs, and 3000 hrs and checked for first evidence of cracking. Using a light table, the laminated structures were inspected for cracks in the layers. If a crack was not visible at a given interval, it was considered to pass the test. If a crack was visible at a given interval, it was considered to fail the test.

### Moisture Vapor Transmission Rate

Moisture vapor transmission rate was determined according to ASTM F1249 at 37.8° C. and 100% relative humidity.

### Intrinsic Viscosity Test Method

Intrinsic viscosity was measured on the film as described in ASTM D4603-03 with the exception that the solvent used to dissolve the film 60:40 w/w phenol/dichlorobenzene.

### Acid End Group Test Method

Acid end group (AEG) concentration of the aged PET film was measured by titration using a Metrohm Titrino 799 system as generally described in ASTM D7409-07 except for the following variations to the film sample: weight, solvent, solvent temperature, titrant, and titrant solvent, which are described below. A 2 g sample of PET was dissolved in N-Methyl-2-pyrrolidone (NMP) solvent at 200° C. The solution was titrated against 0.05 N tetrabutylammonium hydroxide (TBAH) dissolved in methanol by potentiometric method. The amount of TBAH required to complete the titration with the PET solution was measured and used to calculate the concentration of AEG. The method followed ASTM D 7409-07 with the exceptions noted above.

### Apparent Crystal Size Determination Method

Apparent Crystal Size was determined using x-ray diffraction and was estimated by PET (100) diffraction maximum. The (100) crystal planes for biaxially drawn PET tend to align with the film plane so there is an exceptional signal from them. The crystallite size evaluated for the (100) plane measures the crystal size in one of the lateral directions relative to the molecular axis. Samples were examined as direct on a zero background silicon insert. Reflection geometry data were collected in the form of a survey scan by use of a PANalytical Empyrean diffractometer, copper K_{α} radiation, and PIXcel detector registry of the scattered radiation. The diffractometer was fitted with variable incident beam slits and fixed diffracted beam slits. The survey scan was conducted in a coupled continuous mode from 5 to 55 degrees (2θ) using a 0.04 degree step size and 2400 second dwell time. X-ray generator settings of 40 kV and 40 mA were employed.

Observed diffraction peaks were subjected to profile fitting using a Pearson VII peak shape model, cubic spline background model, and X-ray diffraction analysis software (JADE, v9.1, sold by Materials Data Incorporated, Livermore, Calif.). Peak widths were taken as the full width at half maximum (FWHM) of the K_{α1} component. Apparent crystallite sizes (Dₐₚₚ) were determined using the Scherrer equation and observed peak FWHM values after corrections for instrumental broadening and employing a shape factor of 0.9.

Scherrer equation

Dₐₚₚ=Kλ/β cos(θ) (result in Å)

where: K=0.90 shape factor

λ=1.540598 Å wavelength Cu K_{α1}

β=peak FWHM value (in radians) after correction for instrumental broadening

θ=half of the peak position 2θ

### Comparative Example 1

A sample of 3M™ Scotchshield™ Film 15T having a 250 micrometer (10 mil) ethylenevinylacetate (EVA) layer bonded to a polyethyelenterphthlate (PET/PET) film of 2.9 mils thickness and a tetrafluoroethylene-hexafluoropropylene-vinylidenefluoride (THV) layer of nominally 30 micrometers (1.2 mil) as the outermost layer. The PET in the 3M™ Scotchshield™ Film 15T product has an intrinsic viscosity (IV) of 0.51 dLg and end groups of 25 mEq/kg. The PET film was prepared by a well-known process referred to as tentering, which orients the PET molecules in the machine as well as transverse direction. The film was sequentially or simultaneously biaxially stretched by conventionally recognized techniques at a heat set temperature of about 235° C. The PET film also included titanium dioxide particles to opacify the film. The PET film had an apparent crystal size of 70 Angstroms (Å).

A 25 cm×30 cm (10 inches×12 inches) film of 3M™ Scotchshield™ Film 15T, commercially available from 3M Company, St. Paul, Minn. and sold as a backsheet for photovoltaic cells, was laminated to glass containing a layer of 0.46 mm (18 mil) ethylenvinylacetate (EVA) encapsulant (commercially available from Saint Gobain under the trade name “LightSwitch”). The lamination was carried out by positioning the EVA layer of the 3M™ Scotchshield™ Film 15T adjacent to the EVA on the glass and then laminating these two layers together using a NPC laminator 160×110-S (Tokyo, Japan) at 145° C. by evacuating for 4 min and then pressing for 11 min.

The resulting assembly was subjected to the “Pressure Cooker Test Method” described above. After 72 hours, the sample had cracks. The resulting assembly was subjected to the “Damp Heat Test” described above. After 3000 hours, the sample had cracks.

### Comparative Example 2

The same process and construction as described above for Comparative Example 1 was used except the THV layer and adhesive were omitted.

The resulting assembly was subjected to the “Pressure Cooker Test Method” described above. After 72 hours, the sample had cracks. The resulting assembly was subjected to the “Damp Heat Test” described above. After 3000 hours, the sample had cracks.

### Comparative Example 3

The same process and construction as described above for Comparative Example 1 was used except instead of the Scotchshield™ Film 15T film, a 114 micrometers (4.5 mil) thick PET film was used. The PET had an IV of 0.65 dL/g and end groups of 18 mEq/kg. The film area after stretching was about 14 times the area prior to stretching, and the average heat set temperature was 225° C. The PET film had an apparent crystal size of 59 Angstroms (Å).

The resulting assembly was subjected to the “Pressure Cooker Test Method” described above. After 100 hours, the sample had cracks.

### Comparative Example 4

To the exposed surface of the 114 micrometer (4.5 mil) thick PET film described in Comparative Example 3 was adhered, via the tie layer in the 3M™ Scotchshield™ Film 15T product, a 5 mil layer of white pigmented EVA. On the surface of that was a 0.5 mil layer of clear EVA. Both EVA layers were made from commercially available resin from Celanese under the trade name “Ateva 1241.” The white filled layer was obtained by mixing in 13 weight percent of titanium dioxide from a commercially available masterbatch “8000EC” from Schulman Company. The EVA used had a MVTR of 18 g/m²-day.

The resulting assembly was subjected to the “Pressure Cooker Test Method” described above. After 106 hours, the sample had cracks.

### Comparative Example 5

Using the same process described in Comparative Example 3, a 125 micrometers (5 mils) PET film was made. The PET film included 7.5% by weight titanium dioxide particles. The PET film had an IV of 0.65 dL/g and end groups of 18 mEq/kg. The PET film had an apparent crystal size of 55 Angstroms (Å).

Example 1

Using the 114 micrometer (4.5 mil) thick PET film described in Comparative Example 3, to one surface was adhered, via the tie layer in the 3M™ Scotchshield™ Film 15T product, a 25 micrometer (1 mil) thick THV fluoropolymer layer (commercially available as “DYNEON THV 610G” sold by 3M Company, St. Paul, Minn. (having a MVTR of 1.3 g/m2-day). To the other surface of the PET was adhered, via the same tie layer, the layers of white and clear EVA described in Comparative Example 4. The clear layer of EVA was then laminated to glass using the same method described in Comparative Example 1.

The resulting assembly was subjected to the “Pressure Cooker Test Method” described above. After 126 hours, the sample had cracks. The sample was tested according to the “Damp Heat Test Method” and showed no cracking after 3000 hrs. Elongation at break for the PET films described above after various times of Pressure Cooker Testing are indicated in Table 1.

TABLE 1
Elongation at Break (%)

| | 0 hrs | 24 hrs | 48 hrs | 72 hrs | 96 hrs |
|---|---|---|---|---|---|
| | Pressure | Pressure | Pressure | Pressure | Pressure |
| | Cooker | Cooker | Cooker | Cooker | Cooker |
| | Testing | Testing | Testing | Testing | Testing |
| Comp. Ex. 1 | 104 | 88 | 18 | 1.5 | 0 |
| Example 1 | 120 | 125 | 130 | 74 | 2.5 |

### Example 2

An assembly was made using the same procedure described in Example 1, except that the 5 mil PET film from Comparative Example 5 was used in place of the 4.5 mil PET film. The resulting assembly was subjected to the “Pressure Cooker Test Method” described above. After 126 hours, the sample had cracks. The sample was tested according to the “Damp Heat Test Method” and showed no cracking after 3000 hrs.

The present application allows for the combination of any of the disclosed elements.

As used herein, the terms “a”, “an”, and “the” are used interchangeably and mean one or more; “and/or” is used to indicate one or both stated cases may occur, for example A and/or B includes, (A and B) and (A or B).

All references mentioned herein are incorporated by reference.

Unless otherwise indicated, all numbers expressing feature sizes, amounts, and physical properties used in the present disclosure and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein.

As used in this specification and the appended claims, the singular forms “a”, “an”, and “the” encompass embodiments having plural referents, unless the content clearly dictates otherwise. As used in this disclosure and the appended claims, the term “or” is generally employed in its sense including “and/or” unless the content clearly dictates otherwise.

Various embodiments and implementation of the present disclosure are disclosed. The disclosed embodiments are presented for purposes of illustration and not limitation. The implementations described above and other implementations are within the scope of the following claims. One skilled in the art will appreciate that the present disclosure can be practiced with embodiments and implementations other than those disclosed. Those having skill in the art will appreciate that many changes may be made to the details of the above-described embodiments and implementations without departing from the underlying principles thereof. It should be understood that this disclosure is not intended to be unduly limited by the illustrative embodiments and examples set forth herein and that such examples and embodiments are presented by way of example only with the scope of the disclosure intended to be limited only by the claims set forth herein as follows. Further, various modifications and alterations of the present disclosure will become apparent to those skilled in the art without departing from the spirit and scope of the present disclosure. The scope of the present application should, therefore, be determined only by the following claims.

1. A multilayer film for use as a backsheet in a photovoltaic module, comprising:
a first layer including a fluoropolymer;
a second layer including a polyethylene terephthalate having an apparent crystal size of less than about 65 angstroms; and
a third layer including a polymer,
wherein the first layer and the third layer are bonded to opposing major surfaces of the second layer;
wherein the polyethylene terephthalate in the polyethylene terephthalate layer is crystallized; and
wherein the polyethylene terephthalate layer shrinks less than 1.5% of its total length in either planar direction when exposed to a temperature of 150° C. during a period of 15 minutes.

2. The multilayer film of claim 1, wherein the polyethylene terephthalate has an intrinsic viscosity of at least 0.63.

3. The multilayer film of either of claim 1, wherein the polyethylene terephthalate has an intrinsic viscosity of at least 0.70.

4. The multilayer film of any of claim 1, wherein the polyethylene terephthalate has less than about 23 milliequivalents per kilogram of acid end groups.

5. The multilayer film of any of claim 1, wherein the polyethylene terephthalate has less than 20 milliequivalents per kilogram of acid end groups.

6. The multilayer film of claim 1, wherein the multilayer film exhibits no visual cracks after 3000 hours after Damp Heat Testing.

7. The multilayer film of claim 1, wherein the multilayer film exhibits no visual cracks after 96 hours of Pressure Cooker Testing.

8. The multilayer film of claim 1, wherein the multilayer film exhibits no visual cracks after 100 hours of Pressure Cooker Testing.

9. The multilayer film of any of claim 1, wherein the multilayer film exhibits no visual cracks after 110 hours of Pressure Cooker Testing.

10. The multilayer film of claim 1, wherein the multilayer film exhibits no visual cracks after 120 hours of Pressure Cooker Testing.

11. The multilayer film of claim 1, wherein the first layer includes at least one of interpolymerized units of fluorinated monomers and non-fluorinated monomers.

12. The multilayer film of claim 1, wherein the fluoropolymer is semi-crystalline.

13. The multilayer film of claim 1, wherein the third layer includes interpolymerized units of ethylene vinyl actetate.

14. The multilayer film of claim 1, further comprising:
a tie layer between at least one of (a) the first layer and the second layer and (b) the second layer and the third layer.

15. The multilayer film of claim 1, further comprising:
an adhesive layer between at least one of (a) the first layer and the second layer and (b) the second layer and the third layer.

16. The multilayer film claim 1, wherein the multilayer film includes a silane, and the silane is in at least one of the following layers: the first layer, the second layer, the third layer, a layer between the first layer and the second layer, and a layer between the second layer and the third layer.

17. An article comprising the multilayer film of claim 1 applied to a substrate.

18. The article of claim 17, wherein the substrate is a solar cell.

19. A solar module including the multilayer film of claim 1.

20. (canceled)

21. (canceled)

22. (canceled)

23. (canceled)

24. (canceled)

25. (canceled)

26. (canceled)

27. (canceled)

28. (canceled)

29. (canceled)

30. (canceled)

31. (canceled)

32. (canceled)

33. (canceled)

34. (canceled)

35. (canceled)

36. (canceled)

37. (canceled)

38. (canceled)

39. (canceled)

40. (canceled)

41. (canceled)

42. (canceled)

43. (canceled)

44. (canceled)

45. (canceled)

46. (canceled)

47. (canceled)

48. (canceled)

49. (canceled)

50. (canceled)

51. (canceled)

52. A method of making a multilayer film, comprising:
providing a layer including a polyethylene terephthalate having an apparent crystal size of less than about 65 angstroms; and
positioning a barrier layer adjacent to the layer including polyethylene terephthalate;
wherein the polyethylene terephthalate in the polyethylene terephthalate layer is crystallized; and
wherein the polyethylene terephthalate layer shrinks less than 1.5% of its total length in either planar direction when exposed to a temperature of 150° C. during a period of 15 minutes.

53. (canceled)

54. (canceled)

55. (canceled)

56. (canceled)

57. (canceled)

58. (canceled)

59. (canceled)
